(19) United States
(12) Patent Application Publication
(10) Pub. No.: US 2014/0233771 A1
(43) Pub. Date: Aug. 21, 2014

(54) APPARATUS FOR FRONT AND REAR SPEAKER AUDIO CONTROL IN A DEVICE

(71) Applicant: barnesandnoble.com llc, New York, NY (US)

(72) Inventors: Giancarlo Anthony Giustina, San Francisco, CA (US); William Alan Saperstein, San Carlos, CA (US)

(21) Appl. No.: 13/771,715

(22) Filed: Feb. 20, 2013

(51) Int. Cl. H04R 5/04; H03G 3/20

(52) U.S. Cl. CPC H04R 5/04; H03G 3/20
USPC 381/304

(57) ABSTRACT

Techniques for audio control for an electronic device are discussed. The audio control for front and rear speaker channel configuration facilitates supporting proper audio stereo sound based at least in part on an orientation of the electronic device.

### RELATED APPLICATIONS

This application is related to U.S. application Ser. No. xx/xxx,xxx (Attorney Docket BN01.821US) filed Feb. 20, 2013 and titled “Techniques for Front and Rear Speaker Audio Control in a Device” which is herein incorporated by reference in its entirety.

### FIELD OF THE DISCLOSURE

The present disclosure relates to speaker audio control in a device.

### BACKGROUND

Typical electronic devices include speakers to enjoy audio from movies, digital music, and other applications. Presently, various form factors of electronic devices for tablets, laptops, and cell phones allow for multiple speakers in different configurations. However, some device orientations are not supported for stereo sound, such as, the landscape orientation for FIG. 1. In this example, the device does not play stereo music and sounds monaural because the speakers are directly above and below each other.

### SUMMARY

One embodiment of the present invention provides a method for speaker audio control. The method for speaker audio control assigns different channels based at least in part on an orientation of the device. In one embodiment, the orientation of the device is detected by a sensor module. In this embodiment, the sensor module could be a proximity sensor that has an optical light emitter and detector. In yet another embodiment, the sensor module could be an accelerometer.

One embodiment of the present invention provides a method for speaker audio control based at least in part on the number of speakers. The present embodiments teach audio control for speakers for at least two speakers based on orientation.

One embodiment of the present invention provides a method for speaker audio control based on the speaker configuration of the device on whether the speakers are diagonal from each other or cover the outside perimeter of the device.

### BRIEF DESCRIPTION OF THE DRAWINGS

FIG. 1 shows the prior art.

FIGS. 2A and 2B shows multiple apparatus with multiple speaker configurations, in accordance with multiple embodiments of the present invention.

FIG. 3 shows a method for front speaker audio control, in accordance with one embodiment of the present invention.

FIG. 4 shows an apparatus with internal logic controls, in accordance with one embodiment of the present invention.

FIG. 5 shows a method for rear speaker audio control, in accordance with one embodiment of the present invention.

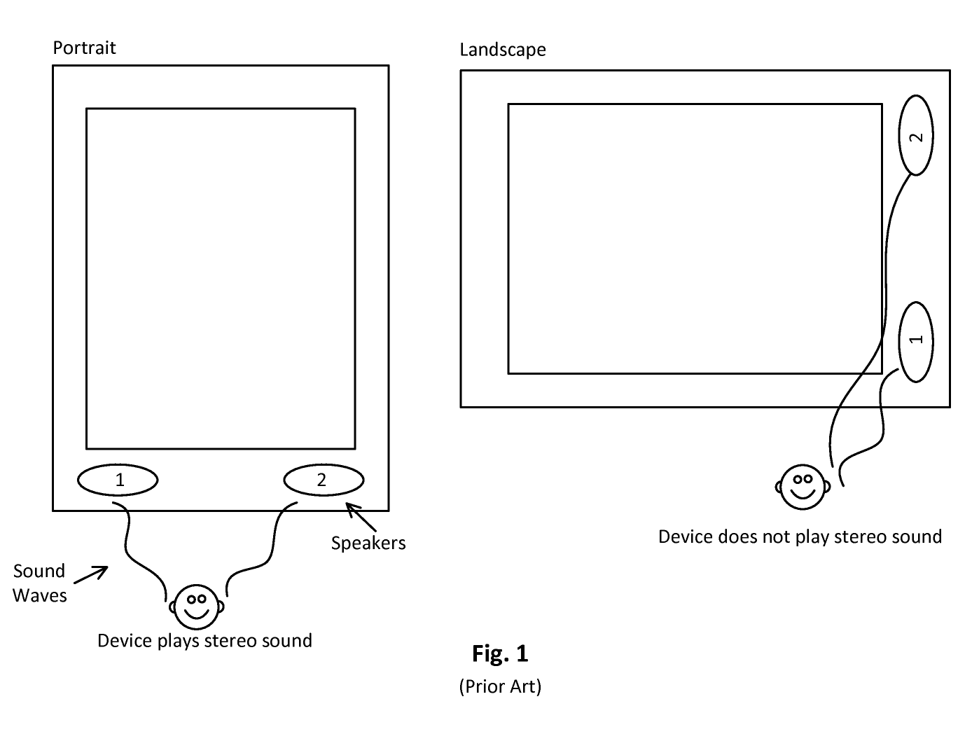

### DETAILED DESCRIPTION

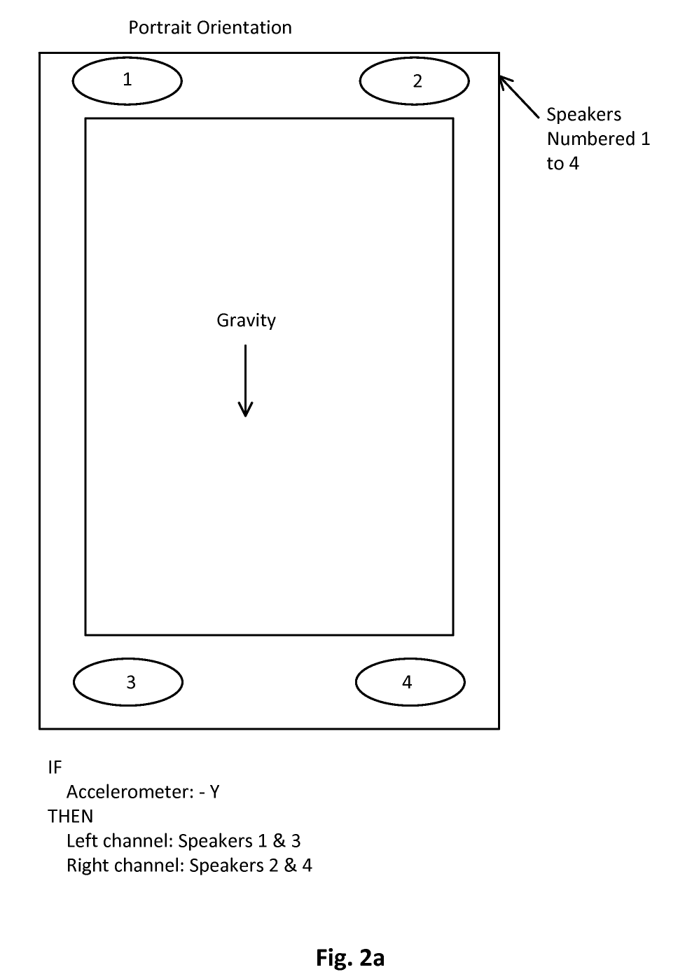

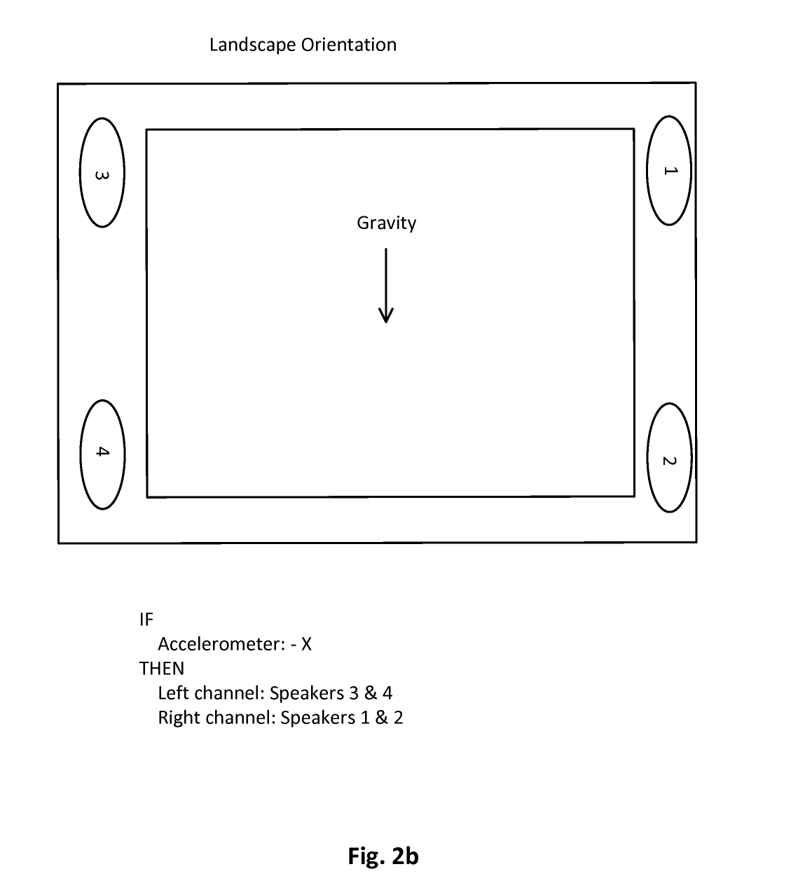

FIGS. 2A and 2B shows multiple apparatus with multiple speaker configurations, in accordance with multiple embodiments of the present invention. Referring to FIG. 2A, the depicted embodiment shows an electronic device with four speakers on each edge of the device and the speakers are labeled as 1, 2, 3, and 4. In an alternative embodiment, only two speakers may be used in a diagonal configuration, such as, utilizing only speakers 2 and 3 or speakers 1 and 4.

For both of the previous embodiments of two and four speaker configurations, FIG. 2A represents a device in a portrait orientation.

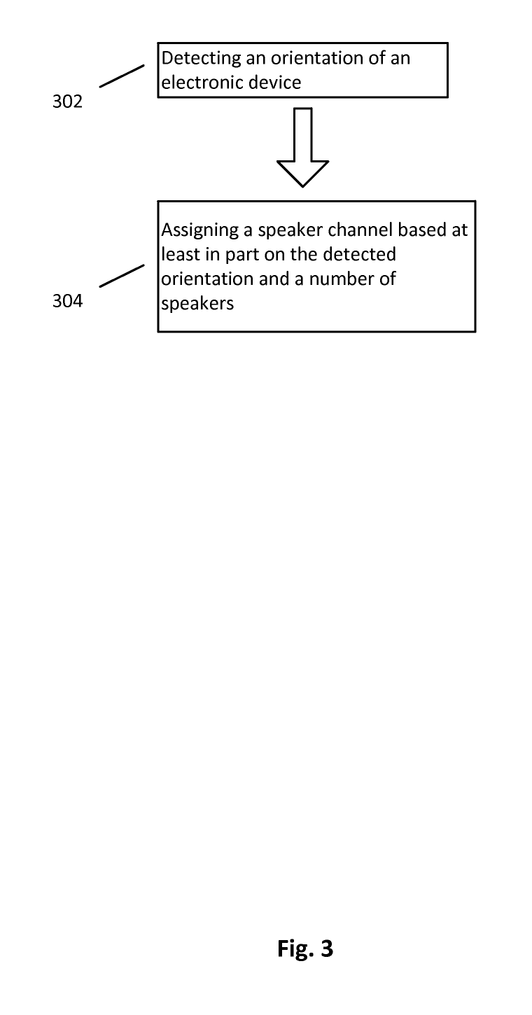

In the embodiment with four speakers, the claimed subject matter utilizes a method to detect device orientation to assign speaker channels to the designated speakers. This method is depicted in connection with FIG. 3. In one embodiment, if the method depicts a device in a portrait orientation, the left speaker channel is assigned to speakers 1 and 3 and the right speaker channel is assigned to speakers 2 and 4. In one embodiment, software may assign the speaker channels for only a two speaker configuration. For this embodiment, hardware controls may be used to assign left and right speaker channels for four speakers.

In the embodiment with two speakers, the claimed subject matter utilizes a method to detect device orientation to assign speaker channels to the designated speakers. This method is depicted in connection with FIG. 3. In one embodiment, if the method depicts a device in a portrait orientation, the left speaker channel is assigned to speaker 1 and the right speaker channel is assigned to speaker 4. In another embodiment, if the method depicts a device in a portrait orientation, the left speaker channel is assigned to speaker 3 and the right speaker channel is assigned to speaker 2.

For both of the previous embodiments of two and four speaker configurations, FIG. 2B represents a device in a landscape orientation.

In the embodiment with four speakers, the claimed subject matter utilizes a method to detect device orientation to assign speaker channels to the designated speakers. This method is depicted in connection with FIG. 3. In one embodiment, if the method depicts a device in a landscape orientation, the left speaker channel is assigned to speakers 3 and 4 and the right speaker channel is assigned to speakers 1 and 2. In one embodiment, software may assign the speaker channels for only a two speaker configuration. For this embodiment, hardware controls may be used to assign left and right speaker channels for four speakers.

In the embodiment with two speakers, the claimed subject matter utilizes a method to detect device orientation to assign speaker channels to the designated speakers. This method is depicted in connection with FIG. 3. In one embodiment, if the method depicts a device in a landscape orientation, the left speaker channel is assigned to speaker 1 and the right speaker channel is assigned to speaker 4. In another embodiment, if the method depicts a device in a landscape orientation, the left speaker channel is assigned to speaker 3 and the right speaker channel is assigned to speaker 2.

FIG. 3 shows a method for speaker audio control, in accordance with one embodiment of the present invention. In this method, detecting an orientation of a device is performed as depicted by label 302. As previously discussed, the detection of the orientation may be performed by a proximity sensor or an accelerometer. Consequently, assigning a speaker channel based at least in part on the detected orientation and number of speakers is performed, as indicated by label 304.

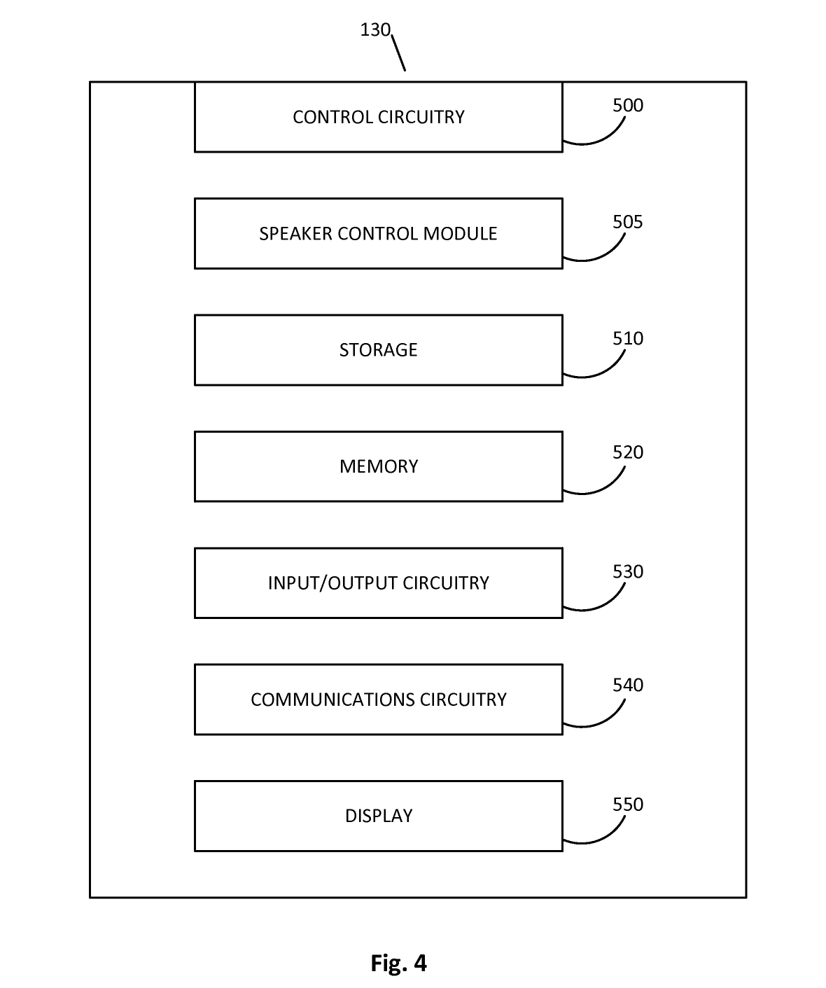

The method may be incorporated in software to reside in random access memory 520 as depicted in FIG. 4. The software facilitates issuing instructions to the electronic device for assigning the speaker channels based on the previous methods discussed.

FIG. 4 illustrates exemplary device 200. As appreciated by those skilled the art, the device 200, can take many forms capable of operating the present invention. In a preferred embodiment the device 200 is a mobile electronic device. Device 200 can include control circuitry 500, storage 510, memory 520, input/output (“I/O”) circuitry 530, communications circuitry 540, and display 550. In some embodiments, one or more of the components of device 200 can be combined or omitted, e.g., storage 510 and memory 520 may be combined. As appreciated by those skilled in the art, device 200 can include other components not combined or included in those shown in this Figure, e.g., a power supply such as a battery, an input mechanism, etc.

Device 200 can include any suitable type of electronic device. For example, electronic device 200 can include a portable electronic device that the user may hold in his or her hand, such as a digital media player, a personal e-mail device, a personal data assistant (“PDA”), a cellular telephone, a handheld gaming device, a tablet device or an eBook reader. As another example, device 200 can include a larger portable electronic device, such as a laptop computer. The invention can also operate on a desktop computer, and can be run through a web application.

Control circuitry 500 can include any processing circuitry or processor operative to control the operations and performance of e device 200. For example, control circuitry 500 can be used to run operating system applications, firmware applications, media playback applications, media editing applications, or any other application. Control circuitry 500 can drive the display 550 and process inputs received from a user interface, e.g., the display 550 if it is a touch screen.

Speaker Control Module 505 includes the hardware and software required to perform the speaker audio controls described herein. For example, the speaker control module could include either the proximity sensor or accelerometer previously discussed. Also, the speaker control module controls the front and rear speaker controls discussed in connection with FIGS. 2, 3, and 5.

Storage 510 can include, for example, one or more computer readable storage mediums including a hard-drive, solid state drive, flash memory, permanent memory such as ROM, magnetic, optical, semiconductor, paper, or any other suitable type of storage component, or any combination thereof. Storage 510 can store, for example, media content, e.g., eBooks, music and video files, application data, e.g., software for implementing functions on electronic device 200, firmware, user preference information data, e.g., content preferences, authentication information, e.g., libraries of data associated with authorized users, transaction information data, e.g., information such as credit card information, wireless connection information data, e.g., information that can enable electronic device 200 to establish a wireless connection, subscription information data, e.g., information that keeps track of podcasts or television shows or other media a user subscribes to, contact information data, e.g., telephone numbers and email addresses, calendar information data, and any other suitable data or any combination thereof. The instructions for implementing the functions of the present invention may, as non-limiting examples, comprise software and/or scripts stored in the computer-readable media 510.

Memory 520 can include cache memory, semi-permanent memory such as RAM, and/or one or more different types of memory used for temporarily storing data. In some embodiments, memory 520 can also be used for storing data used to operate electronic device applications, or any other type of data that can be stored in storage 510. In some embodiments, memory 520 and storage 510 can be combined as a single storage medium.

I/O circuitry 530 can be operative to convert, and encode/decode, if necessary analog signals and other signals into digital data. In some embodiments, I/O circuitry 530 can also convert digital data into any other type of signal, and vice-versa. For example, I/O circuitry 530 can receive and convert physical contact inputs, e.g., from a multi-touch screen, i.e., display 550, physical movements, e.g., from a mouse or sensor, analog audio signals, e.g., from a microphone, or any other input. The digital data can be provided to and received from control circuitry 500, storage 510, and memory 520, or any other component of electronic device 200. Although I/O circuitry 530 is illustrated in this Figure as a single component of electronic device 200, several instances of I/O circuitry 530 can be included in electronic device 200.

Device 200 can include any suitable interface or component for allowing a user to provide inputs to I/O circuitry 530. For example, device 200 can include any suitable input mechanism, such as a button, keypad, dial, a click wheel, or a touch screen, e.g., display 550. In some embodiments, electronic device 200 can include a capacitive sensing mechanism, or a multi-touch capacitive sensing mechanism.

In some embodiments, electronic device 200 can include specialized output circuitry associated with output devices such as, for example, one or more audio outputs. The audio output can include one or more speakers, e.g., mono or stereo speakers, built into device 200, or an audio component that is remotely coupled to electronic device 200, e.g., a headset, headphones or earbuds that can be coupled to device 200 with a wire or wirelessly.

Display 550 includes the display and display circuitry for providing a display visible to the user. For example, the display circuitry can include a screen, e.g., an LCD screen that is incorporated in device 200. In some embodiments, the display circuitry can include a coder/decoder (Codec) to convert digital media data into analog signals. For example, the display circuitry or other appropriate circuitry within electronic device can include video Codecs, audio Codecs, or any other suitable type of Codec.

The display circuitry also can include display driver circuitry, circuitry for driving display drivers, or both. The display circuitry can be operative to display content, e.g., media playback information, application screens for applications implemented on the electronic device 200, information regarding ongoing communications operations, information regarding incoming communications requests, or device operation screens, under the direction of control circuitry 500. Alternatively, the display circuitry can be operative to provide instructions to a remote display.

Communications circuitry 540 can include any suitable communications circuitry operative to connect to a communications network and to transmit communications, e.g., data from the electronic device 200 to other devices within the communications network. Communications circuitry 540 can be operative to interface with the communications network using any suitable communications protocol such as, for example, Wi-Fi, e.g., a 802.11 protocol, Bluetooth, radio frequency systems, e.g., 900 MHz, 1.4 GHz, and 5.6 GHz communication systems, infrared, GSM, GSM plus EDGE, CDMA, quadband, and other cellular protocols, VOIP, or any other suitable protocol.

Electronic device 200 can include one more instances of communications circuitry 540 for simultaneously performing several communications operations using different communications networks, although only one is shown in this Figure to avoid overcomplicating the drawing. For example, electronic device 200 can include a first instance of communications circuitry 540 for communicating over a cellular network, and a second instance of communications circuitry 540 for communicating over Wi-Fi or using Bluetooth. In some embodiments, the same instance of communications circuitry 540 can be operative to provide for communications over several communications networks.

In some embodiments, device 200, can be coupled to a host device such as a cloud for data transfers, synching the communications device, software or firmware updates, providing performance information to a remote source, e.g., providing riding characteristics to a remote server, or performing any other suitable operation that can require electronic device 200 to be coupled to a host device. Several electronic devices 200 can be coupled to a single host device using the host device as a server. Alternatively or additionally, electronic device 200 can be coupled to several host devices, e.g., for each of the plurality of the host devices to serve as a backup for data stored in device 200.

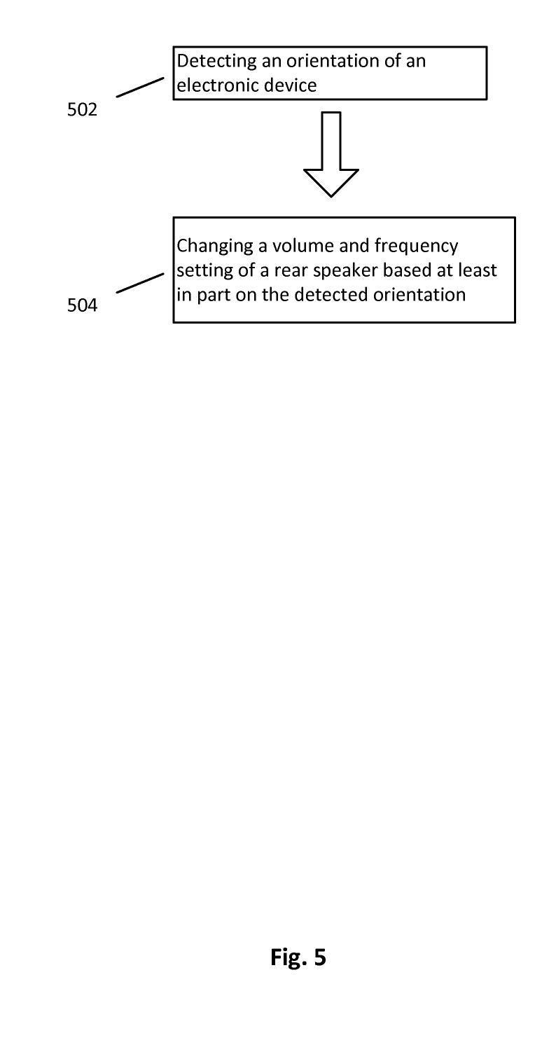

FIG. 5 depicts a method for rear speaker audio control. In this embodiment, detecting on orientation of an electronic device to determine whether the device is vertical or horizontal is performed by block 502. Subsequently, changing a volume and a frequency setting for a rear speaker for the electronic device based at least in part on the detected orientation is performed by block 504.

For example, for one embodiment, if the detection of the orientation indicates a vertical position, the volume and high frequency response of the rear speaker may be decreased by a predetermined level while the low frequency response of the rear speaker is increased. Also, in another embodiment, if the detection of the orientation indicates a horizontal position, the volume and high frequency response of the rear speaker may be increased by a predetermined level while the low frequency response of the rear speaker is decreased.

Although the present invention has been described in relation to particular embodiments thereof, many other variations and other uses will be apparent to those skilled in the art. It is preferred, therefore, that the present invention be limited not by the specific disclosure herein, but only by the gist and scope of the disclosure.

What is claimed is:

1. An electronic device comprising:
a speaker control module to detect an orientation of the electronic device and a number of front facing speakers of the electronic device;
a first and a second front facing speaker, coupled to the speaker control module, to be assigned a speaker channel based on the detected orientation of the electronic device; and
the speaker control module to control a volume and a frequency response of a rear speaker based on the orientation of the electronic device.

2. The electronic device of claim 1 wherein:
the speaker control module to assign a first speaker channel to a first and a second speaker on a same side of the electronic device if the detection indicates four front facing speakers for the electronic device; and
to assign the second speaker channel to a third and a fourth front facing speaker on a different side of the electronic device if the detection indicates four speakers for the electronic device.

3. The electronic device of claim 1 wherein:
the speaker control module to a first speaker channel to a first speaker if the detection indicates two front facing speakers for the electronic device; and
to assign the second speaker channel to a second speaker on a diagonal from the first front facing speaker of the electronic device if the detection indicates two front facing speakers for the electronic device.

4. The electronic device of claim 1 wherein the speaker control module comprises an accelerometer that senses a gravity direction to determine either a vertical or a horizontal orientation.

5. The electronic device of claim 1 wherein the speaker control module comprises a proximity sensor to determine either a horizontal or vertical orientation.

6. A audio control circuit comprising:
an input to the audio control circuit from a sensor to determine a nearly vertical or horizontal orientation of an electronic device;
the audio control circuit to output a volume and a frequency response to a rear facing speaker based at least in part on the vertical or horizontal orientation of the electronic device.

7. The audio control circuit of claim 6 wherein a volume and a high frequency response is increased if the sensor indicates a horizontal orientation.

8. The audio control circuit of claim 6 wherein a volume and a high frequency response is decreased if the sensor indicates a vertical orientation.

9. The audio control circuit of claim 6 wherein a low frequency response is increased if the sensor indicates a vertical orientation.

10. The audio control circuit of claim 6 wherein a low frequency response is decreased if the sensor indicates a horizontal orientation.
